(19) United States
(12) Patent Application Publication
(10) Pub. No.: US 2022/0052242 A1
(43) Pub. Date: Feb. 17, 2022

(54) DISPLAY DEVICE

(71) Applicant: Japan Display Inc., Tokyo (JP)

(72) Inventors: Masanobu IKEDA, Tokyo (JP); Yoshinori AOKI, Tokyo (JP); Akihiro OGAWA, Tokyo (JP)

(21) Appl. No.: 17/398,696

(22) Filed: Aug. 10, 2021

(30) Foreign Application Priority Data
Aug. 17, 2020 (JP) 2020-137651

(51) Int. Cl. H01L 33/62; H01L 27/15; H01L 25/075; H01L 33/38

(52) U.S. Cl. CPC H01L 33/62; H01L 33/38; H01L 25/0753; H01L 27/156

(57) ABSTRACT

A display device includes a substrate having a hole, a plurality of pixels provided to the substrate, and a plurality of light emitting elements provided to the respective pixels. the light emitting elements include a first light emitting element having a predetermined chip size, and a second light emitting element having a chip size smaller than the chip size of the first light emitting element, the first light emitting element and the second light emitting element emit light in a common color, and the light emitting elements disposed around the hole include at least one second light emitting element.

### CROSS-REFERENCE TO RELATED APPLICATION

This application claims the benefit of priority from Japanese Patent Application No. 2020-137651 filed on Aug. 17, 2020, the entire contents of which are incorporated herein by reference.

### BACKGROUND

### 1. Technical Field

The present disclosure relates to a display device.

### 2. Description of the Related Art

Display devices with micro light emitting diodes (micro LEDs) serving as light emitting elements have recently been attracting attention (refer to Japanese Translation of PCT International Application Publication No. 2017-529557, for example). In the display devices disclosed in Japanese Patent Application Laid-open Publication No. 2019-215415 and Japanese Patent Application Laid-open Publication No. 2020-13068, a substrate has a hole, such as notch formed by recessing part of the outer peripheral surface of the substrate and a through hole (punch hole) passing through the substrate. The hole of the substrate accommodates a camera or the like.

In such display devices having a hole in the substrate, light output from the light emitting elements may possibly pass through the substrate and leak into the hole.

An object of the present disclosure is to provide a display device that can prevent light leakage into a hole of a substrate.

### SUMMARY

A display device according to a first embodiment of the present disclosure includes a substrate having a hole, a plurality of pixels provided to the substrate, and a plurality of light emitting elements provided to the respective pixels. The light emitting elements includes a first light emitting element having a predetermined chip size, and a second light emitting element having a chip size smaller than the chip size of the first light emitting element, the first light emitting element and the second light emitting element emit light in a common color, and the light emitting elements disposed around the hole include at least one second light emitting element.

A display device according to a second embodiment of the present disclosure includes a substrate having a hole, a plurality of pixels provided to the substrate, a plurality of light emitting elements provided to the respective pixels, and a cathode electrode covering the light emitting elements. The light emitting elements disposed around the hole include at least one third light emitting element, the third light emitting element comprises a p-type cladding layer, an active layer, an n-type cladding layer, and a high-resistance layer stacked in order on the substrate, sheet resistance of the high-resistance layer is higher than sheet resistance of the n-type cladding layer, the high-resistance layer has an opening at a center, and the cathode electrode covers the high-resistance layer and is directly coupled to a center part of the n-type cladding layer through the opening of the high-resistance layer.

A display device according to a fourth embodiment of the present disclosure includes a substrate including a display region provided with a plurality of pixels, a first light emitting element coupled to a first gate line in the display region, and a second light emitting element coupled to a second gate line in the display region. A wiring length of the second gate line in the display region is shorter than a wiring length of the first gate line in the display region, the first light emitting element and the second light emitting element emit light in a common color, and a chip size of the second light emitting element is smaller than a chip size of the first light emitting element.

### BRIEF DESCRIPTION OF THE DRAWINGS

FIG. 1 is a plan view schematically illustrating a display device according to a first embodiment;

FIG. 2 is a plan view of a plurality of pixels;

FIG. 3 is a partially enlarged plan view of the display device according to the first embodiment;

FIG. 4 is a graph of the relation between the current density and the light quantum number per unit time in a light emitting element (inorganic light emitting diode) in each chip size;

FIG. 5 is a circuit diagram of a pixel circuit;

FIG. 6 is a sectional view along line V-V of FIG. 3;

FIG. 7 is a partially enlarged plan view of the display device according to a second embodiment;

FIG. 8 is a sectional view of the light emitting element according to the second embodiment, and more specifically is a sectional view along line VIII-VIII′ indicated by the arrows of FIG. 9;

FIG. 9 is a plan view schematically illustrating a third light emitting element;

FIG. 10 is a graph of the emission distribution characteristics of the third light emitting element including a high-resistance layer having an opening;

FIG. 11 is an enlarged sectional view of an n-type cladding layer and the high-resistance layer;

FIG. 12 is a view for explaining a method for manufacturing the display device according to the second embodiment;

FIG. 13 is a plan view of the display device according to a third embodiment;

FIG. 14 is a sectional view along line XIV-XIV indicated by the arrows of FIG. 13;

FIG. 15 is a plan view of the display device according to a fourth embodiment;

FIG. 16 is a partially enlarged plan view of the display device according to the fourth embodiment;

FIG. 17 is a flowchart of a process performed to cause the light emitting element to emit light by the pixel circuit and changes in voltage of a gate electrode of a drive transistor; and

FIG. 18 is a plan view of the display device according to a fifth embodiment.

### DETAILED DESCRIPTION

Exemplary aspects (embodiments) to embody the present disclosure are described below with reference to the accompanying drawings. The contents described in the embodiments do not limit the present disclosure. Components described below include components easily conceivable by those skilled in the art and components substantially identical therewith. Furthermore, the components described below may be appropriately combined. What is disclosed herein is given by way of example only, and appropriate changes made without departing from the spirit of the present disclosure and easily conceivable by those skilled in the art naturally fall within the scope of the invention. To simplify the explanation, the drawings may possibly illustrate the width, the thickness, the shape, and other elements of each unit more schematically than the actual aspect. These elements, however, are given by way of example only and are not intended to limit interpretation of the present disclosure. In the present specification and the figures, components similar to those previously described with reference to previous figures are denoted by like reference numerals, and detailed explanation thereof may be appropriately omitted.

To describe an aspect where a first structure is disposed on a second structure in the present specification and the accompanying claims, the term “on” includes both of the following cases unless otherwise noted: a case where the first structure is disposed directly on the second structure in contact with the second structure and a case where the first structure is disposed on the second structure with another structure interposed therebetween.

### First Embodiment

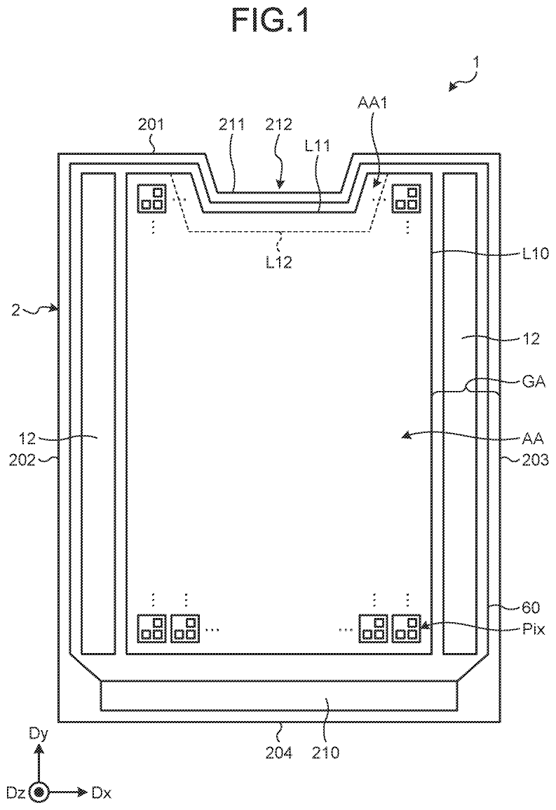

FIG. 1 is a plan view schematically illustrating a display device according to a first embodiment. As illustrated in FIG. 1, a display device 1 includes an array substrate (substrate) 2, pixels Pix, drive circuits 12, a drive integrated circuit (IC) 210, and cathode wiring 60.

The array substrate 2 is a drive circuit substrate that drives the pixels Pix. The array substrate 2 is also called a backplane or an active matrix substrate. The array substrate 2 includes a substrate 21, a plurality of transistors, a plurality of capacitances, various kinds of wiring, and other components. The array substrate 2 has a substantially rectangular shape in planar view. The outer peripheral surface of the array substrate 2 has a first side surface 201, a second side surface 202, a third side surface 203, and a fourth side surface 204. The first side surface 201 extends in a first direction Dx. The second side surface 202 and the third side surface 203 extend in a second direction Dy from both ends of the first side surface 201 in the first direction Dx. The fourth side surface 204 is coupled to the second side surface 202 and the third side surface 203.

While the first direction Dx and the second direction Dy according to the present embodiment intersect at right angles, the angles at which the first direction Dx and the second direction Dy intersect are not necessarily right angles in the display device according to the present disclosure. A third direction Dz is a direction orthogonal to the first direction Dx and the second direction Dy. The third direction Dz corresponds to the normal direction of the substrate 21, for example. Planar view indicates the positional relation viewed from the third direction Dz.

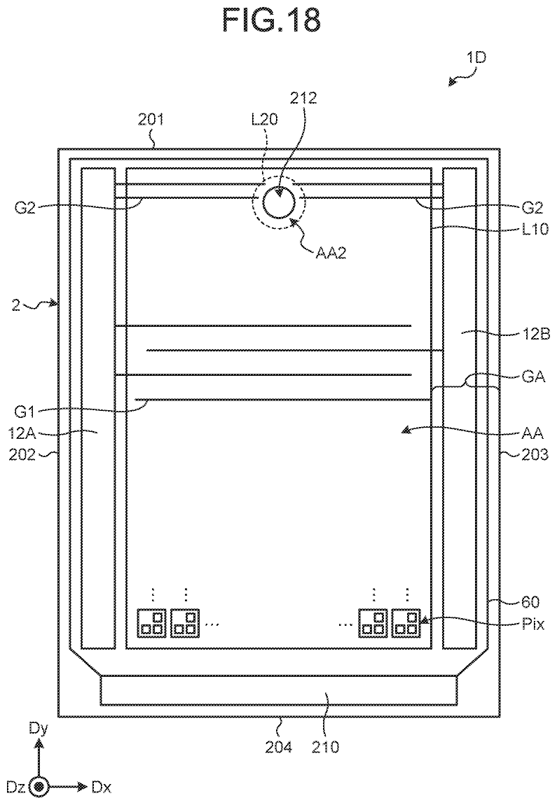

The second side surface 202, the third side surface 203, and the fourth side surface 204 of the array substrate 2 each have a linear shape in planar view. By contrast, the center part of the first side surface 201 in the first direction Dx is partially recessed. In other words, the first side surface 201 has a recess 211. As a result, the array substrate 2 has a notch (hole) 212 formed by recessing part of the first side surface 201. While the notch 212 formed by recessing the outer peripheral surface serves as a hole of the array substrate (substrate) 2 according to the present embodiment, for example, the structure of the display device according to the present disclosure is not limited thereto. The hole may be a punch hole passing through a display region AA of the array substrate (substrate) 2 in the third direction Dz, which will be described later with reference to FIG. 18, for example.

The array substrate 2 has the display region AA and a peripheral region GA. The display region AA is a region for displaying an image and is provided with a plurality of pixels Pix. The peripheral region GA is a region not overlapping the pixels Pix and is positioned outside the display region AA.

Both the display region AA and the peripheral region GA are recessed corresponding to the recess 211 of the array substrate 2. In other words, a boundary line L10 between the display region AA and the peripheral region GA has a recessed line L11 recessed corresponding to the notch 212. In the display region AA, a peripheral part of the recessed line L11 (region between the recessed line L11 and an additional line L12) is referred to as a notch peripheral region AA1. The notch peripheral region AA1 is positioned in the periphery of the notch (hole 212). If first light emitting elements 3R1, 3G1, and 3B1 are disposed in the notch peripheral region AA1, light output from the first light emitting elements 3R1, 3G1, and 3B1 may possibly leak into the notch 212. In other words, the notch peripheral region AA1 is relatively determined by the luminance of the first light emitting elements 3R1, 3G1, and 3B1. If the luminance of the first light emitting elements 3R1, 3G1, and 3B1 is high, the area of the notch peripheral region AA1 increases; and if the luminance of the first light emitting elements 3R1, 3G1, and 3B1 is low, the area of the notch peripheral region AA1 decreases.

The pixels Pix are arrayed at regular intervals in the first direction Dx and the second direction Dy in the display region AA. The ratio at which the pixels Pix are disposed (the filling density or the mounting density of the light emitting elements 3) is uniform in the whole display region AA.

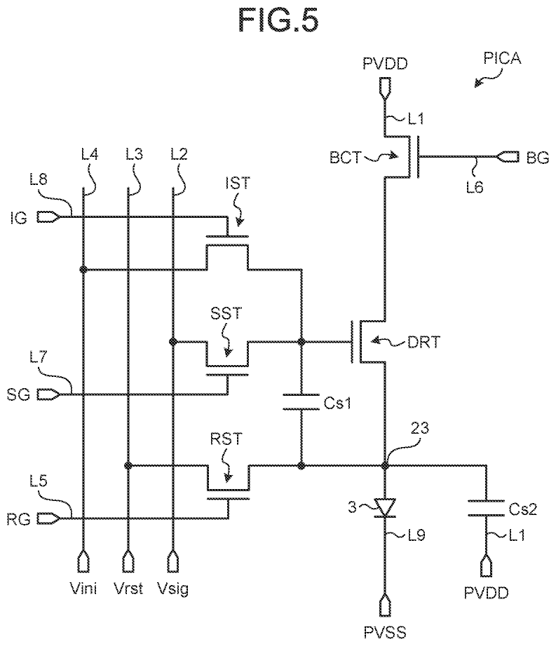

The drive circuits 12 drive a plurality of gate lines (e.g., a reset control signal line L5, an output control signal line L6, a pixel control signal line L7, and an initialization control signal line L8 illustrated in FIG. 5) based on various control signals received from the drive IC 210. The drive circuits 12 sequentially or simultaneously select a plurality of gate lines and supply gate drive signals to the selected gate lines. As a result, the drive circuits 12 select a plurality of pixels Pix coupled to the gate lines.

The drive IC 210 is a circuit that controls display on the display device 1. The drive IC 210 is mounted on the peripheral region GA of the array substrate 2 as chip on glass (COG). The mounting form is not limited thereto, and the drive IC 210 may be mounted on FPCs or a rigid substrate coupled to the peripheral region GA of the array substrate 2 as chip on film (COF).

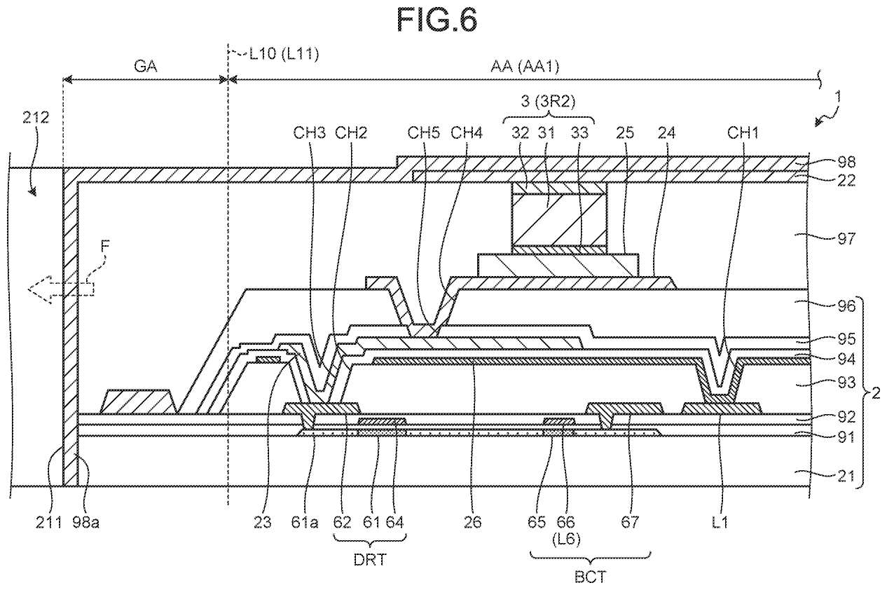

The cathode wiring 60 is provided in the peripheral region GA of the array substrate 2. The cathode wiring 60 is provided surrounding the pixels Pix in the display region AA and the drive circuits 12 in the peripheral region GA. Cathodes of a plurality of light emitting elements 3 are coupled to the common cathode wiring 60 and supplied with a fixed potential (e.g., a ground potential). More specifically, a cathode terminal 32 (refer to FIG. 6) of the light emitting element 3 is coupled to the cathode wiring 60 via a cathode electrode 22.

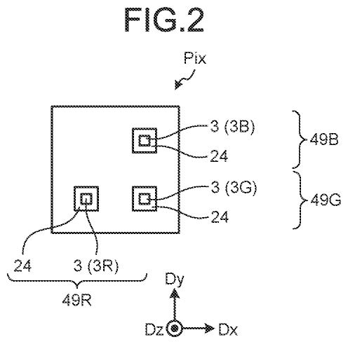

FIG. 2 is a plan view of a plurality of pixels. As illustrated in FIG. 2, one pixel Pix includes a plurality of pixels 49. The pixel Pix includes a pixel 49R, a pixel 49G, and a pixel 49B, for example. The pixel 49R displays a primary color of red as the first color. The pixel 49G displays a primary color of green as the second color. The pixel 49B displays a primary color of blue as the third color. According to the present embodiment, the pixel 49R and the pixel 49G are disposed side by side in the first direction Dx in one pixel Pix. The pixel 49G and the pixel 49B are disposed side by side in the second direction Dy. The first color, the second color, and the third color are not limited to red, green, and blue, respectively, and may be any desired colors, such as complementary colors. In the following description, the pixel 49R, the pixel 49G, and the pixel 49B are referred to as pixels 49 when they need not be distinguished from one another.

The pixels 49 each include the light emitting element 3 and a first mounting electrode 24. The display device 1 outputs different light from light emitting elements 3R, 3G, and 3B in the pixels 49R, 49G, and 49B, respectively, thereby displaying an image. In the display device according to the present disclosure, the light emitting elements 3 may output different light in four or more colors. The positions of the pixels 49 are not limited to those illustrated in FIG. 2. The pixel 49R, for example, may be disposed side by side with the pixel 49B in the second direction Dy. Alternatively, the pixel 49R, the pixel 49G, and the pixel 49B may be repeatedly arrayed in this order in the first direction Dx.

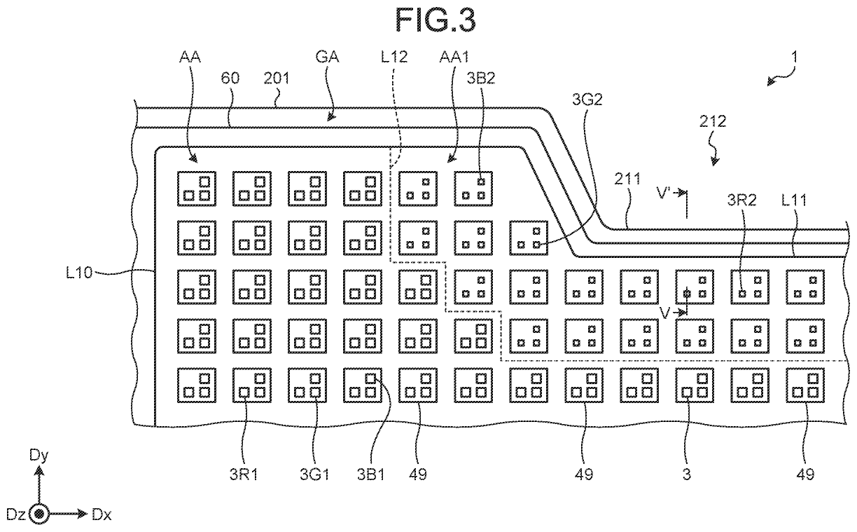

FIG. 3 is a partially enlarged plan view of the display device according to the first embodiment. The light emitting element 3 is an inorganic light emitting diode (LED) chip having a size of approximately 3 μm to 300 μm in planar view. The light emitting element 3 is called a micro LED. The light emitting elements 3 include the first light emitting elements 3R1, 3G1, and 3B1 (refer to FIG. 3) and second light emitting elements 3R2, 3G2, and 3B2. The first light emitting elements 3R1, 3G1, and 3B1 have a predetermined chip size (size in planar view). The second light emitting elements 3R2, 3G2, and 3B2 have a chip size smaller than that of the first light emitting elements 3R1, 3G1, and 3B1. The first light emitting elements 3R1, 3G1, and 3B1 and the second light emitting elements 3R2, 3G2, and 3B2, respectively, emit light in common colors. The pixels 49 disposed in the region other than the notch peripheral region AA1 in the display region AA include the first light emitting elements 3R1, 3G1, and 3B1. By contrast, the pixels 49 disposed in the notch peripheral region AA1 include the second light emitting elements 3R2, 3G2, and 3B2.

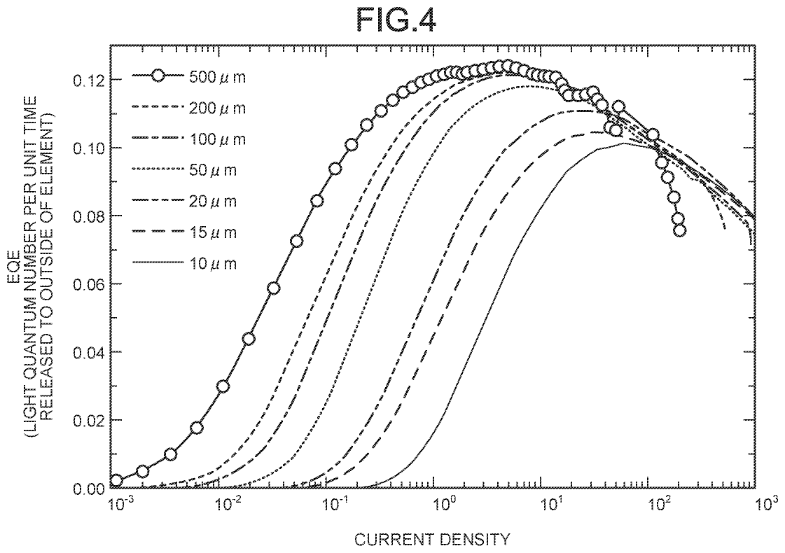

FIG. 4 is a graph of the relation between the current density and the light quantum number per unit time in the light emitting element (inorganic LED) in each chip size. As illustrated in FIG. 4, the inorganic LED has the property that the peak value of the light quantum number per unit time released to the outside decreases as the chip size gradually decreases like 500 μm, 200 μm, 100 μm, 50 μm, 20 μm, 15 μm, and 10 μm. In other words, the light emitting element (inorganic LED) 3 has the property that the luminance decreases as the chip size decreases. In the display device 1 according to the first embodiment, the second light emitting elements 3R2, 3G2, and 3B2 have luminance lower than that of the first light emitting elements 3R1, 3G1, and 3B1.

FIG. 5 is a circuit diagram of a pixel circuit. FIG. 5 illustrates a pixel circuit PICA provided to one pixel 49. The pixel circuit PICA is provided to each of the pixels 49. As illustrated in FIG. 5, the pixel circuit PICA includes the light emitting element 3, five transistors, and two capacitances. Specifically, the pixel circuit PICA includes a drive transistor DRT, an output transistor BCT, an initialization transistor IST, a pixel selection transistor SST, and a reset transistor RST. The drive transistor DRT, the output transistor BCT, the initialization transistor IST, the pixel selection transistor SST, and the reset transistor RST are n-type thin-film transistors (TFTs). The pixel circuit PICA includes first capacitance Cs1 and second capacitance Cs2.

The cathode (cathode terminal 32) of the light emitting element 3 is coupled to a cathode power supply line L9. The anode (anode terminal 33) of the light emitting element 3 is coupled to an anode power supply line L1 via the drive transistor DRT and the output transistor BCT. The anode power supply line L1 is supplied with an anode power supply potential PVDD. The cathode power supply line L9 is supplied with a cathode power supply potential PVSS via the cathode wiring 60 and the cathode electrode 22. The anode power supply potential PVDD is higher than the cathode power supply potential PVSS.

The anode power supply line L1 supplies the anode power supply potential PVDD serving as a drive potential to the pixel 49. Specifically, the light emitting element 3 ideally emits light by being supplied with a forward current (drive current) by a potential difference (PVDD-PVSS) between the anode power supply potential PVDD and the cathode power supply potential PVSS. In other words, the anode power supply potential PVDD has a potential difference to cause the light emitting element 3 to emit light with respect to the cathode power supply potential PVSS. The anode terminal 33 of the light emitting element 3 is electrically coupled to an anode electrode 23. The second capacitance Cs2 serving as an equivalent circuit is coupled between the anode electrode 23 and the anode power supply line L1.

The source electrode of the drive transistor DRT is coupled to the anode terminal 33 of the light emitting element 3 via the anode electrode 23, and the drain electrode thereof is coupled to the source electrode of the output transistor BCT. The gate electrode of the drive transistor DRT is coupled to the first capacitance Cs1, the drain electrode of the pixel selection transistor SST, and the drain electrode of the initialization transistor IST.

The gate electrode of the output transistor BCT is coupled to the output control signal line L6. The output control signal line L6 is supplied with an output control signal BG. The drain electrode of the output transistor BCT is coupled to the anode power supply line L1.

The source electrode of the initialization transistor IST is coupled to an initialization power supply line L4. The initialization power supply line L4 is supplied with an initialization potential Vini. The gate electrode of the initialization transistor IST is coupled to the initialization control signal line L8. The initialization control signal line L8 is supplied with an initialization control signal IG. In other words, the gate electrode of the drive transistor DRT is coupled to the initialization power supply line L4 via the initialization transistor IST.

The source electrode of the pixel selection transistor SST is coupled to a video signal line L2. The video signal line L2 is supplied with a video signal Vsig. The gate electrode of the pixel selection transistor SST is coupled to the pixel control signal line L7. The pixel control signal line L7 is supplied with a pixel control signal SG.

The source electrode of the reset transistor RST is coupled to a reset power supply line L3. The reset power supply line L3 is supplied with a reset power supply potential Vrst. The gate electrode of the reset transistor RST is coupled to the reset control signal line L5. The reset control signal line L5 is supplied with a reset control signal RG. The drain electrode of the reset transistor RST is coupled to the anode electrode 23 (anode terminal 33 of the light emitting element 3) and the source electrode of the drive transistor DRT. A reset operation performed by the reset transistor RST resets the voltage held in the first capacitance Cs1 and the second capacitance Cs2.

The first capacitance Cs1 serving as an equivalent circuit is provided between the drain electrode of the reset transistor RST and the gate electrode of the drive transistor DRT. The pixel circuit PICA can prevent fluctuations in the gate voltage due to parasitic capacitance and current leakage in the drive transistor DRT by the first capacitance Cs1 and the second capacitance Cs2.

In the following description, the anode power supply line L1 and the cathode power supply line L9 may be simply referred to as power supply lines. The video signal line L2, the reset power supply line L3, and the initialization power supply line L4 may be referred to as signal lines. The reset control signal line L5, the output control signal line L6, the pixel control signal line L7, and the initialization control signal line L8 may be referred to as gate lines.

The gate electrode of the drive transistor DRT is supplied with an electric potential corresponding to the video signal Vsig (or gradation signal). In other words, the drive transistor DRT supplies an electric current corresponding to the video signal Vsig to the light emitting element 3 based on the anode power supply potential PVDD supplied via the output transistor BCT. As described above, the anode power supply potential PVDD supplied to the anode power supply line L1 is lowered by the drive transistor DRT and the output transistor BCT. As a result, an electric potential lower than the anode power supply potential PVDD is supplied to the anode terminal 33 of the light emitting element 3.

A first electrode of the second capacitance Cs2 is supplied with the anode power supply potential PVDD via the anode power supply line L1, and a second electrode of the second capacitance Cs2 is supplied with an electric potential lower than the anode power supply potential PVDD. In other words, the first electrode of the second capacitance Cs2 is supplied with an electric potential higher than that supplied to the second electrode of the second capacitance Cs2. The first electrode of the second capacitance Cs2 is a counter electrode 26 coupled to the anode power supply line L1 illustrated in FIG. 6, for example. The second electrode of the second capacitance Cs2 is the anode electrode 23 coupled to the source of the drive transistor DRT illustrated in FIG. 6.

In the display device 1, the drive circuits 12 (illustrated in FIG. 1) select a plurality of pixel rows in order from the first row (e.g., the uppermost pixel row in the display region AA in FIG. 1). The drive IC 210 writes the video signals Vsig (video writing potential) to the pixels 49 of the selected pixel row, thereby causing the light emitting elements 3 to emit light. The drive IC 210 supplies the video signals Vsig to the video signal line L2, supplies the reset power supply potential Vrst to the reset power supply line L3, and supplies the initialization potential Vini to the initialization power supply line L4 in each horizontal scanning period. The display device 1 repeats these operations in units of an image of one frame.

The following describes a sectional configuration of the display device 1. FIG. 6 is a sectional view along line V-V of FIG. 3. As illustrated in FIG. 6, the light emitting element 3 is provided on the array substrate 2. The array substrate 2 includes the substrate 21, various transistors, various kinds of wiring, and various insulating films. The substrate 21 is an insulating substrate and is a glass substrate, a resin substrate, or a resin film, for example.

In the present specification, a direction from the substrate 21 toward the light emitting element 3 in a direction perpendicular to the surface of the substrate 21 is referred to as “upper side” or simply as “up”. A direction from the light emitting element 3 toward the substrate 21 is referred to as “lower side” or simply as “down”.

The drive transistor DRT and the output transistor BCT are provided on a first surface of the substrate 21. Semiconductor layers 61 and 65 are provided on the substrate 21. An undercoat film may be provided between the semiconductor layers 61 and 65 and the substrate 21. An insulating film 91 is provided on the substrate 21 to cover the semiconductor layers 61 and 65. The insulating film 91 is a silicon oxide film, for example.

Gate electrodes 64 and 66 are provided on the insulating film 91. In the example illustrated in FIG. 6, the transistors have what is called a top-gate structure. The transistors may have a bottom-gate structure in which the gate electrode is provided under the semiconductor layer. Alternatively, the transistors may have a dual-gate structure in which the gate electrodes are provided both on and under the semiconductor layer.

An insulating film 92 is provided on the insulating film 91 to cover the gate electrodes 64 and 66. The insulating film 92 has a multilayered structure composed of a silicon nitride film and a silicon oxide film, for example. A source electrode 62, a drain electrode 67, and the anode power supply line L1 are provided on the insulating film 92. The source electrode 62 is electrically coupled to the semiconductor layer 61 through a contact hole passing through the insulating films 91 and 92. The drain electrode 67 is electrically coupled to the semiconductor layer 65 through a contact hole formed in the insulating films 91 and 92.

A plurality of insulating films (a first organic insulating film 93, an insulating film 94, an insulating film 95, and a second organic insulating film 96) are provided covering the transistors. The first organic insulating film 93 and the second organic insulating film 96 are made of organic material, such as photosensitive acrylic. The organic material, such as photosensitive acrylic, is excellent in coverability for covering a difference in level of wiring and flatness on the surface compared with inorganic insulating material formed by CVD, for example. The insulating films 94 and 95 are inorganic insulating films and may be made of the same material as that of the insulating films 91 and 92, such as a silicon nitride film.

Specifically, the first organic insulating film 93 is provided on the insulating film 92 to cover the source electrode 62, the drain electrode 67, and the anode power supply line L1. The counter electrode 26, the insulating film 94, and the anode electrode 23 are stacked in order on the first organic insulating film 93. The counter electrode 26 is made of translucent conductive material, such as indium tin oxide (ITO). The counter electrode 26 is coupled to the anode power supply line L1 at the bottom of a contact hole CH1 formed in the first organic insulating film 93.

The insulating film 94 is provided covering the counter electrode 26. The anode electrode 23 faces the counter electrode 26 with the insulating film 94 interposed therebetween. The first organic insulating film 93 and the insulating film 94 have contact holes CH2 and CH3 the bottom surface of which is the source electrode 62. The anode electrode 23 is electrically coupled to the source electrode 62 through the contact holes CH2 and CH3. As a result, the anode electrode 23 is electrically coupled to the drive transistor DRT.

The anode electrode 23 has a multilayered structure composed of titanium (Ti) and aluminum (Al), for example. The material of the anode electrode 23 is not limited thereto, and the anode electrode 23 may be made of material including at least one of metals of molybdenum (Mo) and Ti. Alternatively, the anode electrode 23 may be made of alloy including at least one of Mo and Ti or translucent conductive material. The second capacitance Cs2 is formed between the anode electrode 23 and the counter electrode 26 facing with the insulating film 94 interposed therebetween.

The insulating film 95 is provided on the insulating film 94 to cover the anode electrode 23. The second organic insulating film 96 is provided on the insulating film 95. In other words, the first organic insulating film 93 is provided on the drive transistor DRT, and the second organic insulating film 96 is stacked on the first organic insulating film 93. The insulating film 95 is provided between the first organic insulating film 93 and the second organic insulating film 96. The second organic insulating film 96 has a contact hole CH4. The insulating film 95 has a contact hole CH5 overlapping the contact hole CH4. The bottom of the contact holes CH4 and CH5 is provided with the anode electrode 23. The anode electrode 23 is provided facing at least part of the first mounting electrode 24.

The first mounting electrode 24 is provided on the second organic insulating film 96 and electrically coupled to the anode electrode 23 through the contact holes CH4 and CH5. The first mounting electrode 24 has a multilayered structure of Ti and Al like the anode electrode 23. The first mounting electrode 24 may be made of conductive material different from that of the anode electrode 23. The second organic insulating film 96 may be made of organic material different from that of the first organic insulating film 93.

The light emitting elements 3R, 3G, and 3B are mounted on the respective first mounting electrodes 24. The light emitting elements 3 are each mounted such that the anode terminal 33 is in contact with the first mounting electrode 24. A connection member 25 between the anode terminal 33 of the light emitting element 3 and the first mounting electrode 24 may be made of any desired material as long as it can secure satisfactory electrical continuity between the anode terminal 33 and the first mounting electrode 24 and does not damage objects on the array substrate 2. The connection member 25 is made of solder or conductive paste, for example. Examples of the method for connecting the anode terminal 33 and the first mounting electrode 24 include, but are not limited to, reflowing using low-temperature melting soldering material, placing the light emitting element 3 on the array substrate 2 with conductive paste interposed therebetween and burning and bonding them, etc.

A semiconductor layer 31 is made of a compound semiconductor, such as gallium nitride (GaN), aluminum indium phosphorous (AlInP), and indium gallium nitride (InGaN). The semiconductor layer 31 may be made of different materials depending on the light emitting elements 3R, 3G, and 3B. The active layer may have a multi-quantum well structure (MQW structure) in which well layers and barrier layers composed of several atomic layers are cyclically stacked for high efficiency. In the light emitting element 3, the semiconductor layer 31 may be formed on a semiconductor substrate.

In the display device 1 according to the present disclosure, the light emitting element 3 may be mounted directly on the anode electrode 23 without the second organic insulating film 96 or the first mounting electrode 24 on the array substrate 2. Providing the second organic insulating film 96 and the first mounting electrode 24 can prevent the insulating film 94 from being damaged by force applied in mounting the light emitting element 3. In other words, the second organic insulating film 96 and the first mounting electrode 24 can prevent dielectric breakdown between the anode electrode 23 and the counter electrode 26 that form the second capacitance Cs2.

The light emitting element 3 is a face-up light emitting element. The lower part of the light emitting element 3 is electrically coupled to the anode electrode 23, and the upper part of the light emitting element 3 is electrically coupled to the cathode electrode 22. The light emitting element 3 includes a semiconductor layer 31, the cathode terminal 32, and the anode terminal 33.

An element insulating film 97 is provided between a plurality of light emitting elements 3. The element insulating film 97 is made of resin material. The element insulating film 97 covers the side surfaces of the light emitting element 3, and the cathode terminal 32 of the light emitting element 3 is exposed from the element insulating film 97. The element insulating film 97 is flatly formed such that the upper surface of the element insulating film 97 and the upper surface of the cathode terminal 32 produce a single plane. The position of the upper surface of the element insulating film 97 may be different from that of the upper surface of the cathode terminal 32.

The cathode electrode 22 covers a plurality of light emitting elements 3 and the element insulating film 97 and is electrically coupled to the light emitting elements 3. The cathode electrode 22 is made of translucent conductive material, such as ITO. This configuration can efficiently extract light output from the light emitting elements 3 to the outside. The cathode electrode 22 is electrically coupled to the cathode terminals 32 of the light emitting elements 3 mounted on the display region AA. The cathode electrode 22 is coupled to the cathode wiring 60 provided on the array substrate 2 at a contact part provided outside the display region AA.

The cathode electrode 22 and the element insulating film 97 are covered with a protective insulating film 98. The protective insulating film 98 is a translucent inorganic insulating film made of insulating material, such as silicon nitride (SiN) and aluminum oxide (Al₂O₃). The protective insulating film 98 has an outer peripheral part 98a covering the side surfaces of the array substrate 2 and the element insulating film 97.

In the display device 1 according to the first embodiment, the second light emitting elements 3R2, 3G2, and 3B2 of the pixels 49 in the notch peripheral region AA1 have luminance relatively lower than that of the first light emitting elements 3R1, 3G1, and 3B1. This configuration reduces the amount of light passing through the outer peripheral part 98a covering the recess 211 and entering into the notch 212 (refer to the arrow F in FIG. 6). Consequently, light leakage into the notch (hole) 212 is prevented. By contrast, the pixels 49 in the region other than the notch peripheral region AA1 are provided with the first light emitting elements 3R1, 3G1, and 3B1. Consequently, the luminance of the pixels 49 in the region other than the notch peripheral region AA1 remains high, thereby maintaining display quality.

While the display device 1000 according to the first embodiment has been described, the display device according to the present disclosure is not limited thereto. Similar effects can be brought about on a display device with flip-chip micro LEDs having a face-down structure. The following describes other embodiments. In the description of the other embodiments, the same components as those described in the first embodiment are denoted by like reference numerals, and overlapping explanation thereof is omitted.

### Second Embodiment

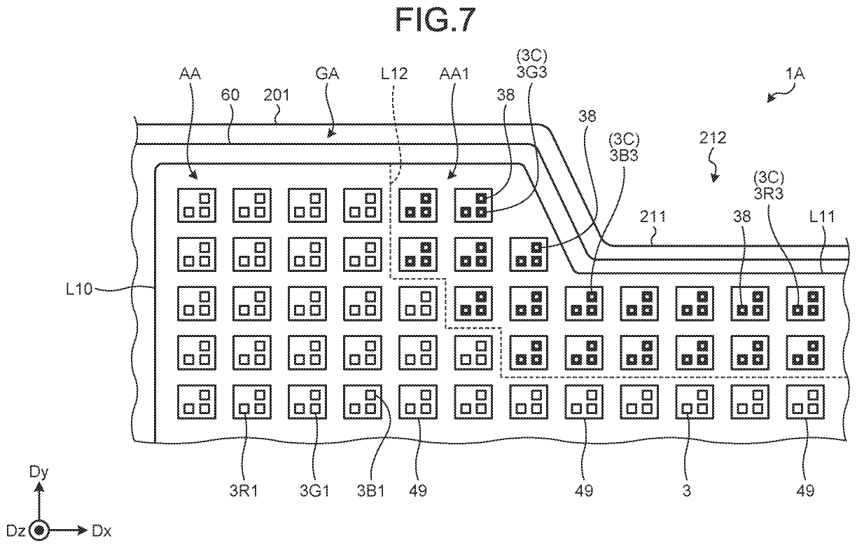

FIG. 7 is a partially enlarged plan view of the display device according to a second embodiment. A display device 1A according to the second embodiment is different from the display device 1 according to the first embodiment in that it includes third light emitting elements 3R3, 3G3, and 3B3 instead of the second light emitting elements 3R2, 3G2, and 3B2. In other words, the display device 1A according to the second embodiment is different from the display device 1 according to the first embodiment in that it includes the third light emitting elements 3R3, 3G3, and 3B3 as the light emitting elements 3 of the pixels 49 in the notch peripheral region AA1. The chip size of the third light emitting elements 3R3, 3G3, and 3B3 is equal to that of the first light emitting elements 3R1, 3G1, and 3B1. In the display device 1A according to the second embodiment, all the light emitting elements 3 of the pixels 49 disposed in the display region AA have the same size. The third light emitting elements 3R3, 3G3, and 3B3 are different from the first light emitting elements 3R1, 3G1, and 3B1 in that they each include a high-resistance layer 38 between the cathode electrode 22 and them. In the following description, the third light emitting elements 3R3, 3G3, and 3B3 are collectively referred to as third light emitting elements 3C. The following describes the third light emitting elements 3C in detail.

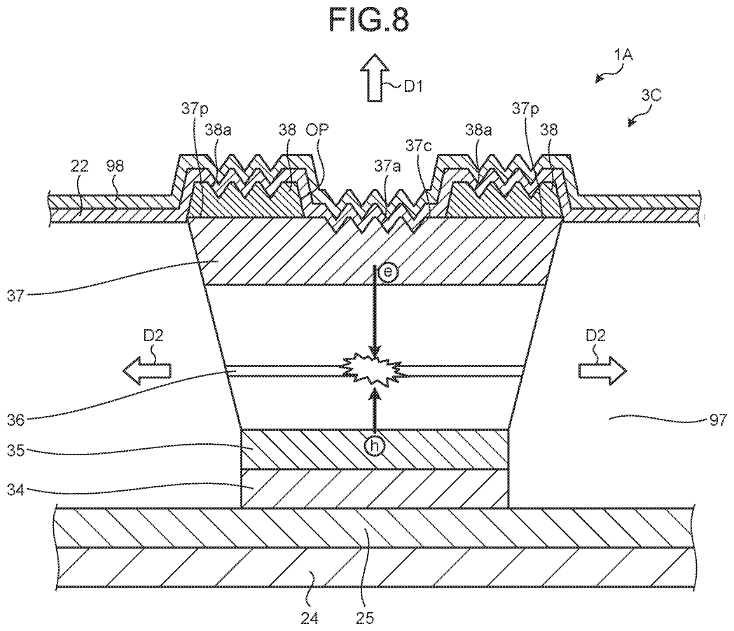

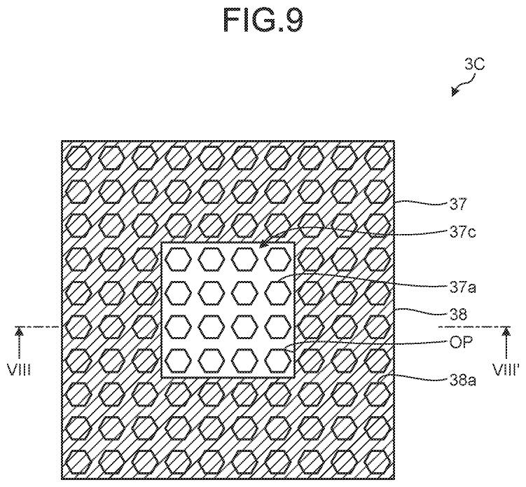

FIG. 8 is a sectional view of the third light emitting element according to the second embodiment, and more specifically is a sectional view along line VIII-VIII′ indicated by the arrows of FIG. 9. FIG. 9 is a plan view schematically illustrating the light emitting element. As illustrated in FIG. 8, the third light emitting element 3C includes a p-type electrode 34, a p-type cladding layer 35, an active layer 36, and an n-type cladding layer 37 stacked in order on the first mounting electrode 24 and the connection member 25. The third light emitting element 3C further includes the high-resistance layer 38 stacked on the n-type cladding layer 37. The high-resistance layer 38 is made of gallium nitride (GaN) doped with no impurities, for example. The sheet resistance of the high-resistance layer 38 is higher than that of the n-type cladding layer 37. The n-type cladding layer 37, the active layer 36, and the p-type cladding layer 35 correspond to the semiconductor layer 31 (refer to FIG. 6) according to the first embodiment. The p-type electrode 34 corresponds to the anode terminal 33 (refer to FIG. 6) according to the first embodiment.

As illustrated in FIG. 9, both the n-type cladding layer 37 and the high-resistance layer 38 have the same square outer shape in planar view. As a result, a peripheral part 37p (refer to FIG. 8) of the n-type cladding layer 37 is covered with the high-resistance layer 38. In the display device according to the present disclosure, the outer shape of the n-type cladding layer 37 and the high-resistance layer 38 is not limited to a square and may be other shapes, such as rectangular, polygonal, and circular shapes.

The high-resistance layer 38 has an opening OP at the center. As a result, the high-resistance layer 38 has a frame shape in planar view. As illustrated in FIG. 8, the cathode electrode 22 covers the high-resistance layer 38 and the n-type cladding layer 37. The cathode electrode 22 is directly coupled to a center part 37c of the n-type cladding layer 37 through the opening OP of the high-resistance layer 38. Consequently, the center part 37c on the upper surface of the n-type cladding layer 37 functions as the cathode terminal 32 (refer to FIG. 6).

With this configuration, the center part 37c of the n-type cladding layer 37 is supplied with the cathode power supply potential PVSS. Consequently, the third light emitting element 3C has a current path only in the center part 37c. As a result, light emission is prevented in the peripheral part 37p compared with the center part 37c, and the center part 37c is more likely to emit light than the peripheral part 37p.

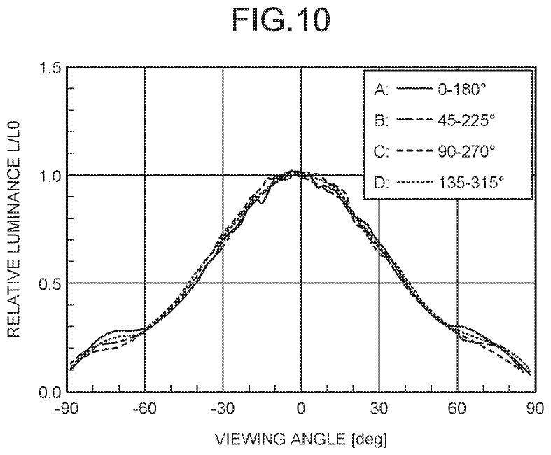

FIG. 10 is a graph of the emission distribution characteristics of the third light emitting element including the high-resistance layer having an opening. In the graph illustrated in FIG. 10, the vertical axis indicates relative luminance, and the horizontal axis indicates viewing angle. The viewing angle indicates an angle (polar angle) inclining with respect to the third direction Dz. The line A indicates a measurement result obtained when a projected line made by projecting the viewing angle on the substrate 21 corresponds to the first direction Dx. The line C indicates a measurement result obtained when a projected line made by projecting the viewing angle on the substrate 21 corresponds to the second direction Dy. The line B indicates a measurement result obtained when a projected line made by projecting the viewing angle on the substrate 21 is at 45 degrees with respect to the first direction Dx and the second direction Dy. The line D indicates a measurement result obtained when a projected line made by projecting the viewing angle on the substrate 21 is at 90 degrees with respect to the projected line of the line B.

As illustrated in FIG. 10, the relative luminance of the third light emitting element 3C has a peak at a higher viewing angle (third direction Dz, that is, the direction indicated by the arrow D1 in FIG. 8). The relative luminance decreases as the viewing angle decreases. The relative luminance is smallest at viewing angles of +90 and −90 degrees (directions indicated by the arrows D2 in FIG. 8).

The refractive index of the protective insulating film 98 and the refractive index of the cathode electrode 22 are lower than that of the n-type cladding layer 37. The refractive index of the n-type cladding layer 37 is approximately 2.4, for example. The refractive index of the cathode electrode 22 is approximately 1.5 to 1.9, for example. The refractive index of the protective insulating film 98 is approximately 1.6 to 2.0, for example.

The difference in the refractive index between the layers is smaller than that between the n-type cladding layer 37 (GaN) and air (the refractive index of which is 1). This configuration can increase the critical angle that yields total reflection on the interface between the layers compared with a case where GaN is provided in contact with air. Consequently, the display device 1A can prevent light output from the third light emitting element 3C from being totally reflected by the interface between the layers. As a result, the display device 1A can increase the light extraction efficiency of the third light emitting element 3C.

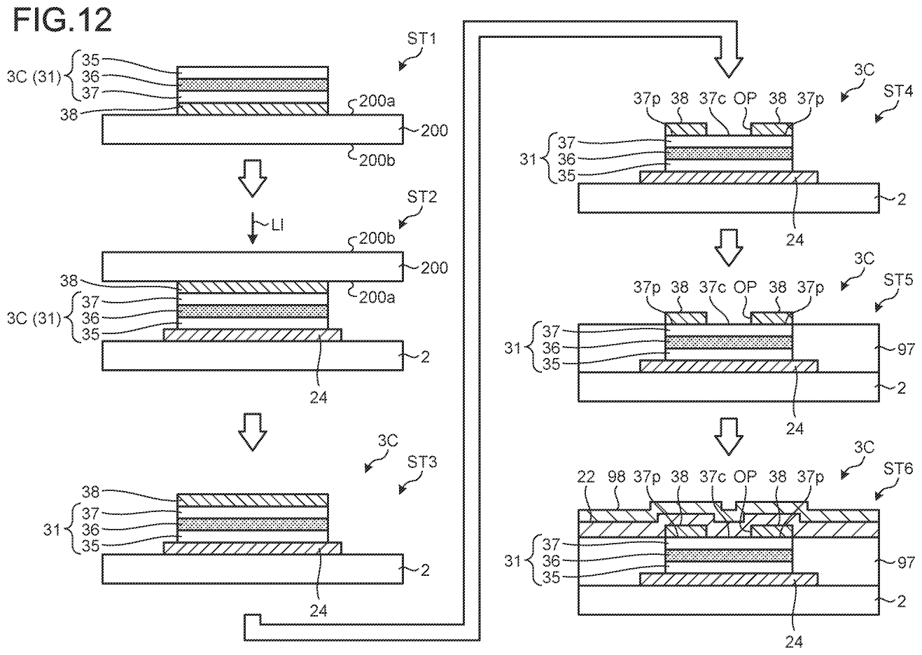

As illustrated in FIG. 8, the upper surface of the n-type cladding layer 37 has a plurality of recesses 37a. The recesses 37a are formed in the center part 37c of the n-type cladding layer 37. The upper surface of the high-resistance layer 38 has a plurality of recesses 38a. The recesses 37a and 38a are formed by transferring the shape of the surface of a sapphire substrate (support array substrate 200, refer to FIG. 12) having a patterned sapphire substrate (PSS) structure. The recesses 37a and 38a have a hexagonal pyramid shape. In other words, the recesses 37a and 38a each have a hexagonal opening shape in planar view and a tapered shape with inclining side walls. With the recesses 37a and 38a, the third light emitting element 3C can prevent reflection of external light, thereby reducing deterioration of display quality.

The recesses 37a and 38a do not necessarily have a hexagonal pyramid shape and may have other shapes, such as a cone and a triangular pyramid. The recesses 37a and 38a are arrayed in a matrix (row-column configuration) in planar view. The recesses 37a and 38a are not necessarily arrayed in a matrix (row-column configuration) and may be arrayed in other patterns, such as a triangular lattice.

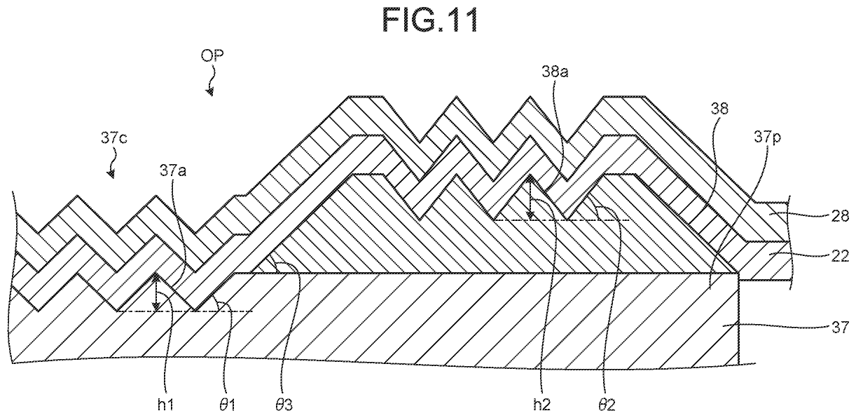

FIG. 11 is an enlarged sectional view of the n-type cladding layer and the high-resistance layer. As illustrated in FIG. 11, an inclination angle (angle θ1) of the side wall of the recess 37a in the center part 37c of the n-type cladding layer 37 is smaller than an inclination angle (angle θ2) of the side wall of the recess 38a on the upper surface of the high-resistance layer 38. In other words, the angle θ1 formed by the side wall of the recess 37a and the direction parallel to the substrate 21 in the center part 37c of the n-type cladding layer 37 is smaller than the angle θ2 formed by the side wall of the recess 38a and the direction parallel to the substrate 21 on the upper surface of the high-resistance layer 38. A height h1 of the recess 37a in the center part 37c of the n-type cladding layer 37 is lower than a height h2 of the recess 38a on the upper surface of the high-resistance layer 38. With this structure, the third light emitting element 3C can increase the light extraction efficiency from the center part 37c of the n-type cladding layer 37.

An angle θ3 formed by the side wall of the high-resistance layer 38 surrounding the opening OP and the direction parallel to the substrate 21 is smaller than the angles θ1 and θ2. An angle of the side wall of the high-resistance layer 38 adjacent to the peripheral part 37p of the n-type cladding layer 37 is also smaller than the angles θ1 and θ2. This structure can prevent step disconnection of the cathode electrode 22 and the protective insulating film 98 covering the high-resistance layer 38.

The following describes a method for manufacturing the display device 1A including the third light emitting elements 3C. FIG. 12 is a view for explaining a method for manufacturing the display device according to the second embodiment. To facilitate the reader's understanding, FIG. 12 illustrates one third light emitting element 3C. In an actual manufacturing process, a number of third light emitting elements 3C and first light emitting elements 3R1, 3G1, and 3B1 are simultaneously mounted on the array substrate 2.

As illustrated in FIG. 12, the semiconductor layer 31 is formed on a first surface 200a of a support array substrate 200 (Step ST1). Specifically, a manufacturing apparatus forms the high-resistance layer 38 made of GaN doped with no impurities, the n-type cladding layer 37, the active layer 36, and the p-type cladding layer 35 in order on the first surface 200a of the support array substrate 200. The support array substrate 200 is a sapphire substrate, for example, and has a PSS structure on the first surface 200a.

Subsequently, the manufacturing apparatus disposes the first surface 200a of the support array substrate 200 so as to face the array substrate 2. The first mounting electrode 24, the connection member 25, and the p-type electrode 34 are stacked in order on the surface of the array substrate 2. FIG. 12 does not illustrate the connection member 25 or the p-type electrode 34. The manufacturing apparatus brings the p-type cladding layer 35 of the semiconductor layer 31 into contact with the first mounting electrode 24. A laser device irradiates the semiconductor layer 31 with laser light LI (Step ST2).

The laser light LI is output from a second surface 200b of the support array substrate 200 and reaches the semiconductor layer 31. The semiconductor layer 31 is irradiated with the laser light LI, absorbs the light, is separated (detached) from the support array substrate 200, and is stacked on the surface of the array substrate 2 (Step ST3). In other words, the manufacturing apparatus detaches the semiconductor layer 31 from the support array substrate 200 by a laser lift-off technology. The high-resistance layer 38 is formed covering the whole surface of the n-type cladding layer 37 on the surface of the semiconductor layer 31. The high-resistance layer 38 and the n-type cladding layer 37 have a plurality of recesses 38a and 37a (refer to FIG. 8), which are not illustrated in FIG. 12, formed by transferring the PSS structure of the support array substrate 200.

The laser light LI is preferably set to a wavelength band in which the laser light LI passes through the support array substrate 200 and is absorbed by the high-resistance layer 38. The laser light LI preferably has an energy of 3.5 eV (electron Volt) to 9.9 eV corresponding to a wavelength band in which the laser light LI passes through sapphire but does not pass through GaN, for example. The wavelength of the laser light LI is preferably set to 310 nm or lower.

Subsequently, the manufacturing apparatus patterns the high-resistance layer 38 (Step ST4). To pattern the high-resistance layer 38, a resist is formed by photolithography, and a center part of the high-resistance layer 38 is removed by dry etching, for example. As a result, the opening OP of the high-resistance layer 38 is formed, and the center part 37c of the n-type cladding layer 37 is exposed. Reactive ion etching (hereinafter, referred to as RIE) can be employed as dry etching.

Subsequently, the manufacturing apparatus forms the element insulating film 97 between the third light emitting elements 3C (Step ST5). The element insulating film 97 covers the side surfaces of the p-type cladding layer 35, the active layer 36, and the n-type cladding layer 37. The element insulating film 97 does not overlap the upper surface (the center part 37c and the peripheral part 37p) of the n-type cladding layer 37 and the high-resistance layer 38.

The manufacturing apparatus forms the cathode electrode 22 and the protective insulating film 98 to cover the third light emitting element 3C and the element insulating film 97 (Step ST6). As a result, the cathode electrode 22 covers the high-resistance layer 38 and is directly in contact with the center part 37c and the peripheral part 37p of the n-type cladding layer 37.

By the process described above, the third light emitting element 3C can be transferred and mounted on the array substrate 2 to manufacture the display device 1A. The manufacturing method illustrated in FIG. 12 is given by way of example only and may be appropriately modified.

In the display device 1A according to the second embodiment, the pixels 49 in the notch peripheral region AA1 include the third light emitting elements 3C (3R3, 3G3, and 3B3). The relative luminance of the third light emitting element 3C is smallest at viewing angles of +90 and −90 degrees (directions indicated by the arrows D2 in FIG. 8). This configuration reduces the amount of light output from the third light emitting elements 3C toward the notch 122. Consequently, light leakage into the notch 122 is prevented.

The light emission area of the third light emitting elements 3R3, 3G3, and 3B3 is restricted by the high-resistance layer 38. In the third light emitting elements 3R3, 3G3, and 3B3, the luminance at a higher viewing angle (third direction Dz, that is, the direction indicated by the arrow D1 in FIG. 8) may possibly be lower than that of the first light emitting elements 3R1, 3G1, and 3B1 in the other region. In the structure according to the second embodiment, the inclination angle (angle θ1) of the side wall of the recess 37a in the center part 37c of the n-type cladding layer 37 is smaller than the inclination angle (angle θ2) of the side wall of the recess 38a on the upper surface of the high-resistance layer 38. This structure increases the light extraction efficiency in the center part 37c of the n-type cladding layer 37 and prevents reduction in luminance of the third light emitting elements 3C. Similar effects can be brought about on a display device with flip-chip micro LEDs having a face-down structure.

### Third Embodiment

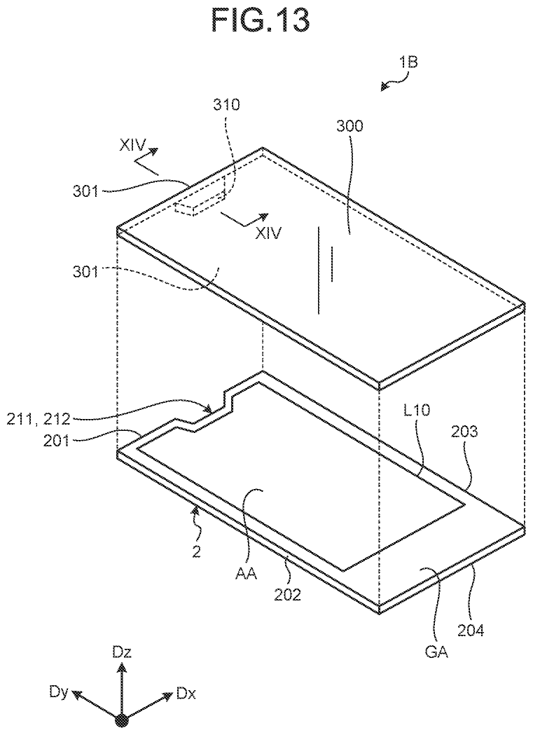

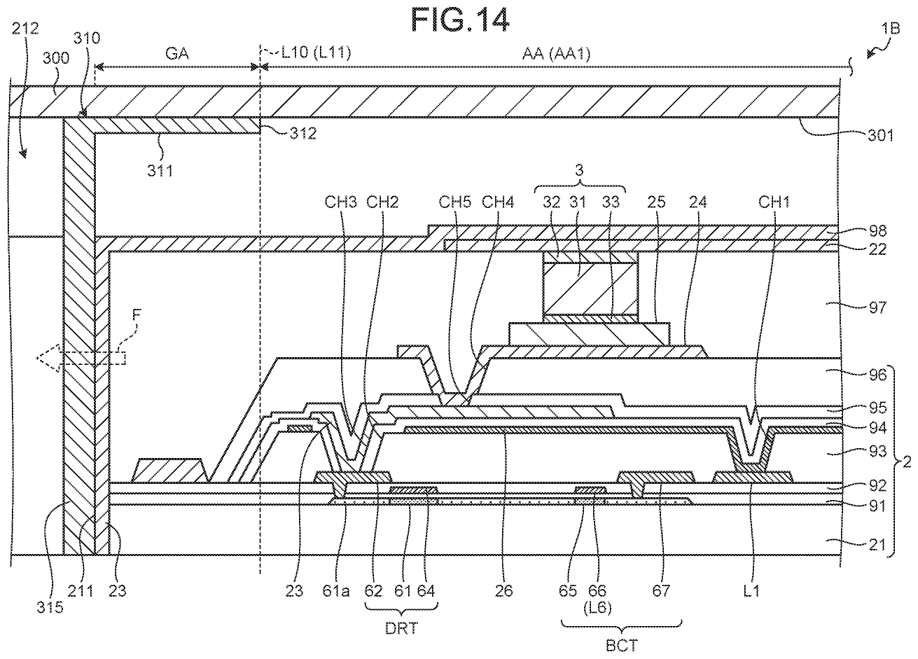

FIG. 13 is a sectional view of the display device according to a third embodiment. FIG. 14 is a sectional view along line XIV-XIV indicated by the arrows of FIG. 13. A display device 1B according to the third embodiment is different from the display device 1 according to the first embodiment in that it includes the first light emitting elements 3R1, 3G1, and 3B1 instead of the second light emitting elements 3R2, 3G2, and 3B2. In other words, all the light emitting elements 3 of the pixels 49 in the display region AA are the first light emitting elements 3R1, 3G1, and 3B1 in the display device 1B according to the third embodiment. The display device 1B according to the third embodiment is different from the display device according to the first embodiment in that it includes a covering member 300 covering the array substrate (substrate) 2.

As illustrated in FIG. 13, the covering member 300 is a plate part made of transmissive material, such as glass. The covering member 300 has a rectangles shape in planar view. In other word, the covering member 300 covers the display region AA and the peripheral region GA of the array substrate 2 and the notch 121. The covering member 300 has a facing surface 301 facing the array substrate 2. The facing surface 301 is provided with a light blocking member 310 having a recessed shape in planar view.

As illustrated in FIG. 14, the light blocking member 310 is made of material having a high light-blocking property. The light blocking member 310 has an L-shaped section along the thickness direction of the covering member 300. The light blocking member 310 includes a flange 311 and a wall 315. The flange 311 faces the covering member 300. The wall 315 covers the recess 211 of the array substrate 2. The flange 311 adheres to the covering member 300 with an adhesive sheet, which is not illustrated.

The flange 311 extends along the facing surface 301 of the covering member 300. The flange 311 adheres to the covering member 300 with an adhesive sheet, which is not illustrated. As a result, the covering member 300 and the light blocking member 310 are integrated. The flange 311 overlaps the peripheral region GA in planar view. In other words, an end 312 of the flange 311 overlaps the boundary line L10 between the display region AA and the peripheral region GA1. As a result, the flange 311 covers the cathode wiring 60 and other components in the peripheral region GA.

The wall 315 has the same shape as that of the recess 211 of the array substrate 2 in planar view. In other words, the wall 315 covers the side surface of the recess 211 of the array substrate 2. This configuration reduces the amount of light output from the light emitting elements 3 and entering into the notch 212 (refer to the arrow F in FIG. 14). Consequently, light leakage into the notch 212 is prevented.

While the first to the third embodiments have been described, the display device according to the present disclosure is not limited to the examples described above. The covering member 300 described in the third embodiment, for example, may be combined with the display device 1 according to the first embodiment and the display device 1A according to the second embodiment. The second light emitting elements 3R2, 3G2, and 3B2 having a small chip size described in the first embodiment may be combined with the high-resistance layer 38 having the opening OP described in the second embodiment. The cathode electrode 22 may cover the high-resistance layer 38 and be directly coupled to the center part of the n-type cladding layer through the opening OP of the high-resistance layer 38. Disposing such light emitting elements 3 in the notch peripheral region AA1 can further prevent light leakage into the notch 212 (hole). Similar effects can be brought about on a display device with flip-chip micro LEDs having a face-down structure.

In the display device according to the present disclosure, all the light emitting elements 3 disposed in the notch peripheral region AA1 are not necessarily the second light emitting elements 3R2, 3G2, and 3B2 described in the first embodiment and the third light emitting elements 3R3, 3G3, and 3B3 described in the second embodiment. In the display device according to the present disclosure, some of the light emitting elements 3 disposed in the notch peripheral region AA1 may be the second light emitting elements 3R2, 3G2, and 3B2 and/or the third light emitting elements 3R3, 3G3, and 3B3, and the others may be the first light emitting elements 3R1, 3G1, and 3B1. Such a display device can also reduce the amount of light output toward the notch 212 and prevent light leakage into the notch 212.

In the display device according to the present disclosure, the second light emitting elements 3R2, 3G2, and 3B2 and/or the third light emitting elements 3R3, 3G3, and 3B3 may be disposed in the region other than the notch peripheral region AA1. In a configuration according to a fourth embodiment described below, the second light emitting elements 3R2, 3G2, and 3B2 are disposed part of the notch peripheral region AA1 and the other region, for example. While the fourth embodiment describes an example where the second light emitting elements 3R2, 3G2, and 3B2 are used, the display device according to the present disclosure may use the third light emitting elements 3R3, 3G3, and 3B3 instead of the second light emitting elements 3R2, 3G2, and 3B2.

### Fourth Embodiment

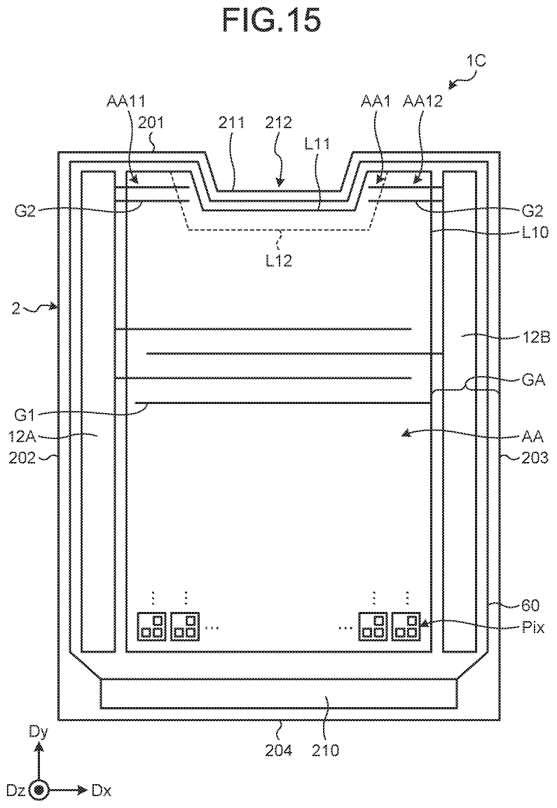

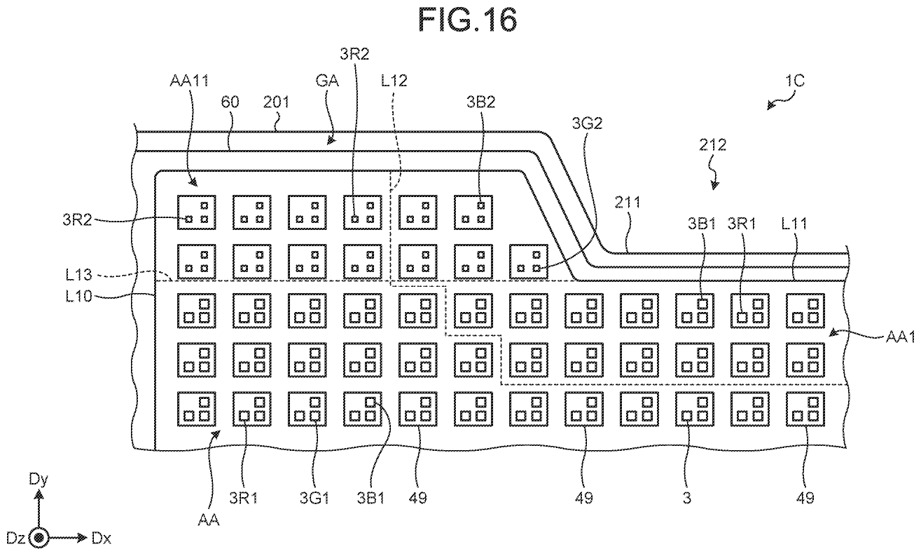

FIG. 15 is a sectional view of the display device according to the fourth embodiment. FIG. 16 is a partially enlarged plan view of the display device according to the fourth embodiment. As illustrated in FIG. 15, the array substrate 2 has the notch (hole) 212. The boundary line L10 between the display region AA and the peripheral region GA1 has the recessed line L11 corresponding to the notch (hole) 212. The recessed line L11 is recessed from the peripheral region GA1 toward the display region AA, that is, from the outer periphery toward the inner periphery of the boundary line L10. As a result, the display region AA has a first region AA11 and a second region AA12 protruding from the inner periphery toward the outer periphery of the boundary line L10 with respect to the recessed line L11. In other words, the display region AA has the first region AA11 and the second region AA12 sandwiching the recessed line L11 in the first direction Dx.

As illustrated in FIG. 16, the first region AA11 is a range surrounded by the boundary line L10 and an additional line L13. The pixels 49 disposed in the first region AA11 include the second light emitting elements 3R2, 3G2, and 3B2 as the light emitting elements 3. The pixels 49 disposed in the second region AA12, which are not illustrated, include the second light emitting elements 3R2, 3G2, and 3B2 as the light emitting elements 3. By contrast, the pixels 49 disposed in the region other than the first region AA11 or the second region AA12 in the display region AA include the first light emitting elements 3R1, 3G1, and 3B1 as the light emitting elements 3.

Some of the second light emitting elements 3R2, 3G2, and 3B2 of the pixels 49 in the first region AA11 and the second region AA12 are disposed in the notch region AA1. Also in a display device 1C according to the fourth embodiment, the luminance of the light emitting elements 3 (second light emitting elements 3R2, 3G2, and 3B2) disposed in part of the notch region AA1 is low. Consequently, light leakage into the notch 212 is prevented.

As illustrated in FIG. 15, the display region AA is provided with a plurality of gate lines (refer to G1 and G2 in FIG. 15) extending in the second direction Dy from drive circuits 12A and 12B. The gate lines collectively denote the reset control signal line L5, the output control signal line L6, the pixel control signal line L7, and the initialization control signal line L8 illustrated in FIG. 5. First gate lines G1 illustrated in FIG. 15 are disposed in the region other than the first region AA11 or the second region AA12. Second gate lines G2 are disposed in the first region AA11 and the second region AA12. The second gate lines G2 are divided in the first direction Dx and made short by the notch (hole) 212 formed between the first region AA11 and the second region AA12. As a result, the light emitting elements 3 in the first region AA11 and the second region AA12 coupled to the short second gate lines G2 may possibly emit light with relatively high luminance. The following describes the mechanism in greater detail.

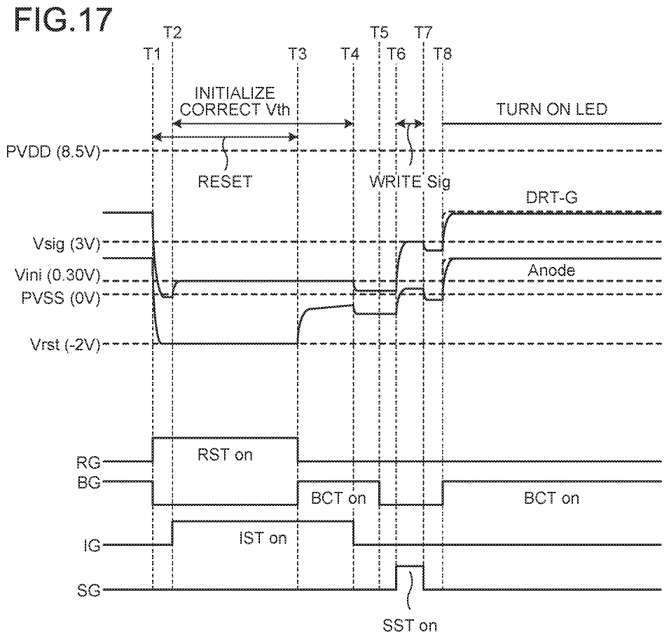

FIG. 17 is a flowchart of a process performed to cause the light emitting element to emit light by the pixel circuit and changes in voltage of the gate electrode of the drive transistor. “DRT-G” in FIG. 17 indicates the voltage value of the gate electrode of the drive transistor DRT. “Anode” in FIG. 17 indicates the voltage value of the anode terminal 33 of the light emitting element 3.

As illustrated in FIG. 17, the pixel circuit goes through a procedure of resetting (from time T1 to time T3), initialization (from time T2 to time T4), and writing Signal (from time T6 to time T7), whereby the light emitting element 3 emits light (after time T8). When the light emitting element 3 starts to emit light (time T8), the output transistor BCT is turned on, and the voltage of the gate electrode of the drive transistor DRT rises corresponding to the amount of writing of Signal. If the gate line coupled to the gate electrode of the output transistor BCT is long (refer to the solid line of DRT-G in FIG. 17), the voltage value of the gate electrode of the drive transistor DRT gradually rises. By contrast, if the gate line is short (refer to the dashed line of DRT-G in FIG. 17), the voltage value of the gate electrode of the drive transistor DRT steeply rises. This is because the short gate line improves (reduces) the time constant.

If the rising of the voltage value of the gate electrode of the drive transistor DRT is improved, the start time of application to the light emitting element 3 (refer to the dashed line of Anode in FIG. 17) is advanced compared with the case where the voltage value gradually rises (refer to the solid line of Anode in FIG. 17). As a result, the time of application to the light emitting element 3R becomes longer. Making the time of application longer increases the luminance of the light emitting element 3.

The display device 1C according to the fourth embodiment includes the substrate, the first light emitting elements 3R1, 3G1, and 3B1, and the second light emitting elements 3R2, 3G2, and 3B2. The substrate has the display region AA provided with the pixels 49. The first light emitting elements 3R1, 3G1, and 3B1 are coupled to the first gate lines G1 in the display region AA. The second light emitting elements 3R2, 3G2, and 3B2 are coupled to the second gate lines G2 in the display region AA. The wiring length of the second gate line G2 in the display region AA is shorter than that of the first gate line G1 in the display region AA. The first light emitting elements 3R1, 3G1, and 3B1 and the second light emitting elements 3R2, 3G2, and 3B2, respectively, emit light in common colors. The chip size of the second light emitting elements 3R2, 3G2, and 3B2 is smaller than that of the first light emitting elements 3R1, 3G1, and 3B1.

In other words, the second light emitting elements 3R2, 3G2, and 3B2 disposed in the first region AA11 and the second region AA12 have a chip size smaller than that of the first light emitting elements 3R1, 3G1, and 3B1 and have luminance lower than that of the first light emitting elements 3R1, 3G1, and 3B1. If the application time becomes longer, the luminance of the light emitting elements 3 (second light emitting elements 3R2, 3G2, and 3B2) disposed in the first region AA11 and the second region AA12 is substantially equal to that of the first light emitting elements 3R1, 3G1, and 3B1.

As described above, the display device 1C according to the fourth embodiment can prevent light leakage into the notch 212. In addition, the display device 1C can reduce the difference in luminance between the light emitting elements 3 disposed in the first region AA11 and the second region AA12 and those disposed in the region other than the first region AA11 or the second region AA12. Consequently, the display device 1C maintains display quality.

In the configuration according to the fourth embodiment, only the pixels 49 in the region overlapping the first region AA11 and the second region AA12 out of the pixels 49 in the notch peripheral region AA1 are provided with the second light emitting elements 3R2, 3G2, and 3B2, for example. In the display device according to the present disclosure, all the pixels 49 disposed in the notch peripheral region AA1, the first region AA11, and the second region AA12 may be provided with the second light emitting elements 3R2, 3G2, and 3B2 or the third light emitting elements 3R3, 3G3, and 3B3. Similar effects can be brought about on a display device with flip-chip micro LEDs having a face-down structure.

### Fifth Embodiment

FIG. 18 is a plan view of the display device according to a fifth embodiment. While the hole according to the first to the fourth embodiments is the notch 212, the hole of a display device 1D according to the fifth embodiment is a through hole 212 passing through the array substrate 2. The through hole 212 may be a recess not passing through the array substrate 2. In addition, the hole according to the present disclosure may be a part not serving as a space like the through hole 212, that is, a transparent region not provided with the pixels or the light emitting elements 3. Specifically, the transparent region is not provided with transistors constituting a plurality of pixels, various kinds of wiring made of metal material, the light emitting elements 3, or other components on the substrate 21. In other words, the transparent region is only provided with various insulating films on the substrate 21 overlapping the transparent region and has transparency higher than that of the display region AA.

The through hole 212 according to the fifth embodiment has a circular shape. The through hole 212 is surrounded by a hole peripheral region AA2. An additional line L20 in FIG. 18 is a boundary line indicating the boundary between the hole peripheral region AA2 and the display region AA. In other words, the part between the additional line L20 and the through hole 212 corresponds to the hole peripheral region AA2. The display device 1D according to the fifth embodiment includes a plurality of first gate lines G1 and a plurality of second gate lines G2. The second gate lines G2 are divided in the second direction Dy and made short by the through hole 212. In other words, the second gate lines G2 are interrupted near the through hole 212. Virtual lines extending the second gate lines G2 overlap the through hole 212. By contrast, the first gate lines G1 are provided away from the through hole 212 and are long because they are not divided. In the display device 1D according to the fifth embodiment, the hole peripheral region AA2 is provided with the pixels including the second light emitting elements 3R2, 3G2, and 3B2 having a small chip size. The display region AA other than the hole peripheral region AA2 is provided with the pixels including the first light emitting elements 3R1, 3G1, and 3B1 having a large chip size. The light emitting elements 3 of the pixels provided in the hole peripheral region AA2 are not limited to the second light emitting elements 3R2, 3G2, and 3B2 and may be the third light emitting elements 3C.

As described above, the display device according to the fifth embodiment can prevent light leakage into the through hole 212 serving as a hole and maintain display quality. Similar effects can be brought about if the hole is a transparent region.

What is claimed is:

1. A display device comprising:
a substrate having a hole;
a plurality of pixels provided to the substrate; and
a plurality of light emitting elements provided to the respective pixels, wherein
the light emitting elements include:
a first light emitting element having a predetermined chip size; and
a second light emitting element having a chip size smaller than the chip size of the first light emitting element,
the first light emitting element and the second light emitting element emit light in a common color, and
the light emitting elements disposed around the hole include at least one second light emitting element.

2. The display device according to the claim 1, wherein
the substrate includes:
a display region provided with the pixels; and
a peripheral region surrounding the display region,
a boundary line between the display region and the peripheral region has a recessed line recessed toward the display region,
the display region includes a first region and a second region sandwiching the recessed line, and
the first region and the second region are provided with the second light emitting element.

3. A display device comprising:
a substrate having a hole;
a plurality of pixels provided to the substrate;
a plurality of light emitting elements provided to the respective pixels; and
a cathode electrode covering the light emitting elements, wherein
the light emitting elements disposed around the hole include at least one third light emitting element,
the third light emitting element comprises a p-type cladding layer, an active layer, an n-type cladding layer, and a high-resistance layer stacked in order on the substrate,
sheet resistance of the high-resistance layer is higher than sheet resistance of the n-type cladding layer,
the high-resistance layer has an opening at a center, and
the cathode electrode covers the high-resistance layer and is directly coupled to a center part of the n-type cladding layer through the opening of the high-resistance layer.

4. The display device according to the claim 3, wherein
the substrate includes:
a display region provided with the pixels; and
a peripheral region surrounding the display region,
a boundary line between the display region and the peripheral region has a recessed line recessed toward the display region,
the display region includes a first region and a second region sandwiching the recessed line, and
the first region and the second region are provided with the third light emitting element.

5. A display device comprising:
a substrate including a display region provided with a plurality of pixels;
a first light emitting element coupled to a first gate line in the display region; and
a second light emitting element coupled to a second gate line in the display region, wherein
a wiring length of the second gate line in the display region is shorter than a wiring length of the first gate line in the display region,
the first light emitting element and the second light emitting element emit light in a common color, and
a chip size of the second light emitting element is smaller than a chip size of the first light emitting element.

6. The display device according to claim 5, wherein
the substrate has a hole, and the hole is a notch formed in a recessed shape along a side surface of the substrate,
the second light emitting element is disposed near the notch, and
the first light emitting element is disposed farther away from the notch than the second light emitting element.

7. The display device according to claim 5, wherein
the substrate has a hole, and the hole is a through hole passing through the substrate and formed in the display region,
the second light emitting element is disposed near the through hole, and
the first light emitting element is disposed farther away from the through hole than the second light emitting element.

8. The display device according to claim 5, wherein
the substrate has a hole, and the hole is a transparent region not provided with the pixels in the display region,
the second light emitting element is disposed near the transparent region, and
the first light emitting element is disposed farther away from the transparent region than the second light emitting element.
